(19) United States
(12) Patent Application Publication
(10) Pub. No.: US 2013/0048054 A1
(43) Pub. Date: Feb. 28, 2013

(54) System and Method for Collection of Solar Energy for Conversion to Electric Power

(71) Applicant: Neil C. Schoen, Gaithersburg, MD (US)

(72) Inventor: Neil C. Schoen, Gaithersburg, MD (US)

(21) Appl. No.: 13/216,557

(22) Filed: Aug. 24, 2011

(51) Int. Cl. H01L 31/058; F03G 6/06; H01L 31/052

(52) U.S. Cl. 136/248; 136/246; 60/641.15

(57) ABSTRACT

According to an embodiment of the present invention, a solar energy collection system utilizes high efficiency multi junction photovoltaic (PV) solar cells to augment extracted energy obtained from a photovoltaic (PV) solar cell coolant fluid Carnot cycle process. The combined Carnot and photovoltaic (PV) energy extraction process significantly enhances the efficiency of solar energy-to-electric power conversion. The solar energy collection system employs a suspension system that further reduces costs of producing electricity.

### BACKGROUND

1. Technical Field

Present invention embodiments pertain to collection of solar energy. In particular, present invention embodiments pertain to a solar energy collection system or apparatus with high efficiency, multi junction solar cells to enhance solar-to-electric power conversion capability. In addition, present invention embodiments employ an efficient suspension system for a solar collector of the solar energy collection system that further reduces costs of producing electric power.

2. Discussion of Related Art

Solar thermal electric generation systems are generally large monolithic, high power systems. Although these types of systems are successful at producing electricity, the cost of the produced electricity greatly exceeds current electricity costs from conventional coal and hydroelectric power systems. Photovoltaic solar power conversion systems are expensive, and have primarily been used to power space satellites.

### SUMMARY

According to an embodiment of the present invention, a solar energy collection system utilizes high efficiency multi-junction photovoltaic (PV) solar cells to augment extracted energy obtained from a photovoltaic (PV) solar cell coolant fluid Carnot cycle process. The combined Carnot and photovoltaic (PV) energy extraction process significantly enhances the efficiency of solar energy-to-electric power conversion. Energy conversion efficiencies for large-scale power plants approaching 70 to 80% appear to be feasible using combined photovoltaic (PV) and thermal solar energy collection systems to attain low (e.g., $0.10 or less per kilowatt-hour) lifetime costs. The cooled, multi-layer photovoltaic solar cells enhance electric power output with little impact to the total cost of construction of the solar energy collection system. The solar energy collection system employs a suspension system that further reduces costs of producing electricity.

The above and still further features and advantages of present invention embodiments will become apparent upon consideration of the following detailed description of example embodiments thereof, particularly when taken in conjunction with the accompanying drawings wherein like reference numerals in the various figures are utilized to designate like components.

### BRIEF DESCRIPTION OF THE DRAWINGS

FIG. 1A is a diagrammatic illustration of a solar energy collection system including dual photovoltaic and thermal energy conversion according to an embodiment of the present invention.

FIG. 1B is a view in elevation of a segmented collector for a solar energy collection system according to embodiments of the present invention.

FIG. 1C is a view in elevation of an alternative embodiment of the segmented collector of FIG. 1B.

FIG. 1D is a top view in plan of a suspension system according to an embodiment of the present invention for supporting a collector of a solar energy collection system.

FIG. 2 is a procedural flowchart illustrating a manner to control the position of the collector of the solar energy collection system of FIG. 1A according to an embodiment of the present invention.

FIG. 3 is a diagrammatic illustration of an alternative solar energy collection system according to an embodiment of the present invention.

FIG. 4 is a procedural flowchart illustrating a manner to control the position of the collector of the solar energy collection system of FIG. 3 according to an embodiment of the present invention.

### DETAILED DESCRIPTION OF EXAMPLE EMBODIMENTS

Present invention embodiments pertain to a solar energy collection system with high efficiency, multi-junction solar cells to enhance solar-to-electric power conversion capability. In addition, present invention embodiments employ an efficient suspension system for the solar collector of the solar energy collection system that further reduces costs of producing electric power.

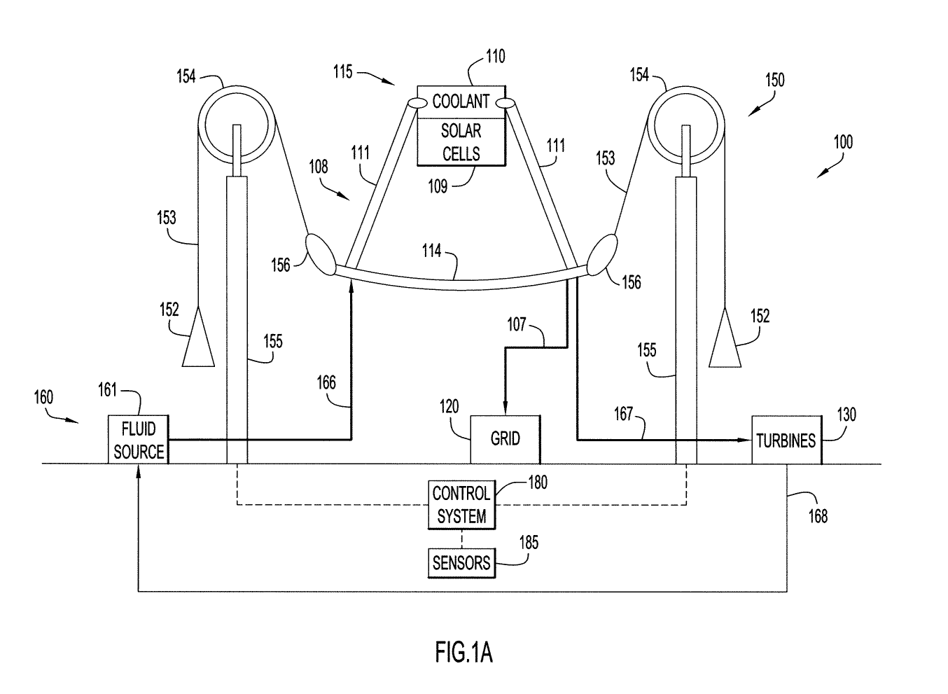

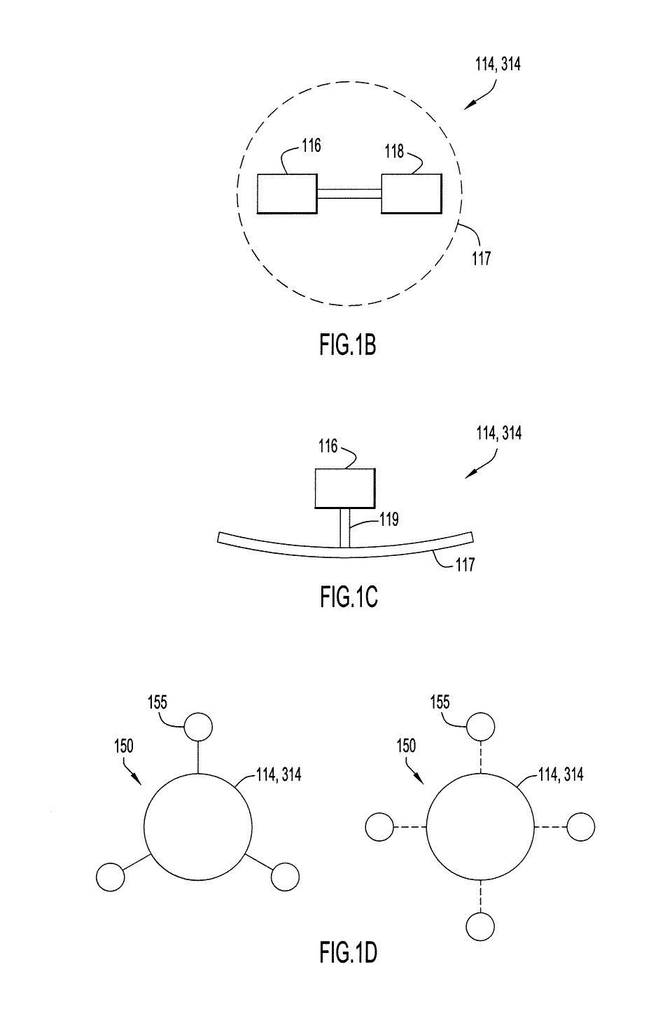

A solar energy collection system according to an embodiment of the present invention is illustrated in FIG. 1A. Specifically, solar energy collection system 100 includes a collector 114, a solar unit 115, a suspension system 150, and a coolant fluid system 160. Collector 114 includes an integral and generally concave reflective surface that concentrates incoming solar energy (e.g., infrared, visible, etc.) onto solar unit 115. The collector is preferably implemented by a mirror, but any suitable reflector may be utilized.

Alternatively, the concave reflective surface of collector 114 may include a segmented surface. Referring to FIG. 1B, the reflective surface of collector 114 may include a plurality of reflective segments 116. The reflective segments each include a reflective surface to reflect solar energy, and have dimensions substantially less than those of collector 114. Each pair of reflective segments is interconnected by one or more connectors 118. Connectors 118 may include flexible (e.g., wires, etc.) or rigid (e.g., rods, etc.) connection members. The reflective segments are arranged to form the generally concave reflective surface of collector 114, where the distance between adjacent reflective segments is preferably minimized (e.g., significantly less than the size of those segments) to limit loss of solar energy and reduce the dimensions of collector 114. The reflective segments may be directly attached to a generally concave substrate 117 (FIG. 1B), or may be displaced from substrate 117 by a post or other member 119 as illustrated in FIG. 1C. In this case, substrate 117 may include a reflective surface to enhance efficiency of solar collection.

Solar unit 115 receives the solar energy reflected from collector 114 to enable conversion to electric power. The solar unit includes one or more layers of multi-junction solar cells 109 and a coolant layer 110. The solar cell layers are preferably arranged in a stacked relation. Solar cells 109 are positioned below the coolant layer in facing relation with collector 114 to receive the solar energy reflected from the collector and convert that solar energy to electric power. The solar cells are preferably positioned within each layer to overlap a prior or succeeding layer in order to maximize the capture of solar energy. Coolant layer 110 is disposed above solar cells 109 and cools the solar cells to prevent damage and optimize electrical output. The coolant layer further extracts thermal energy from solar cells 109 for conversion to electric power as described below to enhance conversion efficiency of solar energy to electric power. The coolant layer further receives thermal energy from residual solar energy not being captured by (or bypassing) solar cells 109 within the layers.

A support structure 108 maintains solar unit 115 (e.g., including solar cells 109 and coolant layer 110 that generate power) at the optimal focus location relative to collector 114 (e.g., the focal point of collector 114). The support structure includes a plurality of rods 111 secured to, and extending between, solar unit 115 and a peripheral area of collector 114 to support the solar unit above the collector. The rods are preferably positioned at substantially equidistant angular positions about collector 114 (e.g., two rods may be displaced from each other by 180°, three rods may be displaced from each other by 120°, etc.), but may be disposed at any suitable positions to support the solar unit.

Coolant fluid system 160 includes a coolant fluid source 161 and fluid conduits 166, 167, 168 to transport coolant fluid. Coolant fluid source 161 provides coolant fluid to solar collection system 100, and may include a thermal treatment device to thermally treat coolant fluid, and a pump or other device to direct the coolant fluid through conduit 166 to solar unit 115. Conduit 166 may be secured to, or disposed within, a rod 111 of support structure 108 to transport coolant fluid from fluid source 161 to solar unit 115. The coolant fluid traverses coolant layer 110 of solar unit 115 to cool solar cells 109 and extract thermal energy therefrom. The coolant fluid further receives thermal energy from residual solar energy not being captured by (or bypassing) solar cells 109 within the layers.

Conduit 167 may be secured to, or disposed within, a rod 111 of support structure 108 to transport heated coolant fluid from solar unit 115 to a conventional electric turbine system 130. The heated coolant fluid may be utilized to generate steam that rotates or otherwise manipulates turbines of electric turbine system 130 to generate electric power. Once the coolant fluid transfers the thermal energy to the electric turbine system, the coolant fluid may return to fluid source 161 for thermal treatment and transfer to solar unit 115. Conduit 168 may be disposed between coolant fluid source 161 and electric turbine system 130 to transport the coolant fluid from the electric turbine system to the fluid source. Conduits 166, 167, 168 may be implemented by any conventional or other conduits suitable for transporting fluids (e.g., tubing, etc.).

An electrical conductor 107 may similarly be secured to, or disposed within, a rod 111 of support structure 108 to transport electrical power from solar unit 115 (e.g., electric output current from solar cells 109) to a conventional power system supply grid 120. The electric power from grid 120 and turbine system 130 may be provided for sale to consumers.

Suspension system 150 supports and pivots collector 114 to track movement of the sun for optimal collection of solar energy. Suspension system 150 includes a plurality of support towers 155 and a control system 180. The support towers are preferably positioned at substantially equidistant angular positions about collector 114. For example, three support towers may be disposed about collector 114 and displaced from each other by 120°, while four support towers may be disposed about collector 114 and displaced from each other by 90° as illustrated in FIG. 1D. However, the towers may be of any quantity and disposed at any suitable positions to support the collector.

Each tower 155 includes a counterweight 152, a suspension cable 153, and a drive wheel 154. One end of suspension cable 153 is secured to a peripheral area of collector 114 (e.g., preferably including a loop, hook or other engagement member 156), while the other end of the suspension cable is secured to counterweight 152. The suspension cable extends from collector 114 to enable an intermediate portion (e.g., a portion between collector 114 and counterweight 152) to engage drive wheel 154. The drive wheel is disposed at an upper portion of tower 155, and is preferably motorized (e.g., driven by a stepper or other motor). Control system 180 controls drive wheels 154 to manipulate suspension cables 153 and pivot collector 114 based on the position of the sun. Counterweights 152 greatly reduce the mechanical stress and power necessary to move the collector to track the sun. This is accomplished by allowing the center of gravity of collector 114 to remain stationary while the collector is pivoted to track the movement of the sun.

The collector position is adjusted based on operation of drive wheels 154 of towers 155. Initially, the collector is suspended below drive wheels 154 of towers 155. Rotation of a drive wheel 154 in a first direction of rotation reels in suspension cable 153 to draw the corresponding peripheral portion of collector 114 upward toward that drive wheel. Conversely, rotation of drive wheels 154 in a second direction of rotation lets out suspension cable 153 to enable the corresponding peripheral portion to move downward. One or more drive wheels may be locked, while other drive wheels may be rotated in order to adjust the orientation of collector 114. For example, in an embodiment employing four towers 155 angularly displaced from each other by 90°, two drive wheels along the azimuth direction may be locked in order to enable the rotation of one or more remaining drive wheels to control elevation. However, any combination of drive wheels may be controlled in any fashion to achieve a desired collector orientation.

The combination of manipulation of drive wheels 154 enable collector 114 to be oriented at various desired angles for substantial alignment with the sun. The quantity of orientation angles to be produced for collector 114 is dependent upon the quantity of towers 155 employed. For example, two towers may enable orientation of collector 114 with respect azimuth or elevation, while three towers may enable orientation of collector 114 with respect to both, but may not quite cover every possible angle. These embodiments typically have a lower collection efficiency since the limited orientation angles for the collector may enable the collector to deviate from alignment with the sun position. Four or more towers substantially cover the spectrum of orientation angles for the collector and provide enhanced collection efficiency; however, the costs of these embodiments are likely to be increased. The solar collection system may employ any quantity of towers based on desired requirements (e.g., costs, collection efficiency, etc.) for a particular application.

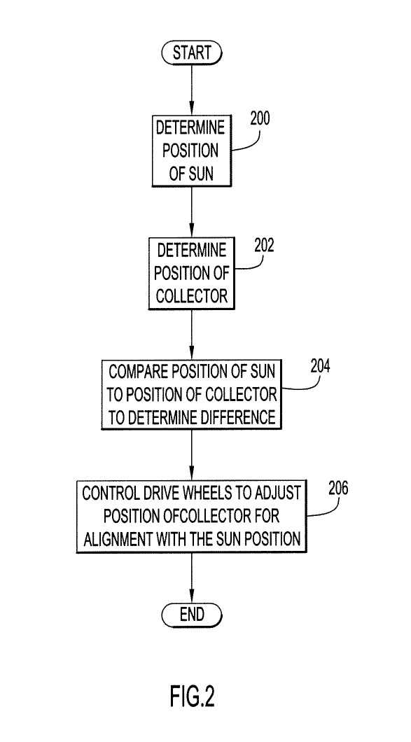

Control system 180 preferably includes a conventional or other processor (e.g., microprocessor, computer system, controller, etc.) with one or more control modules to control drive wheels 154 of support towers 155 to position collector 114. The control modules may be implemented by any quantity or combination of hardware and/or software modules or units. A manner in which control system 180 (e.g., via the one or more control modules) controls the position of collector 114 is illustrated in FIG. 2. Initially, control system 180 is in communication with each of the drive wheels (and/or motors of the drive wheels) 154 to transfer information (e.g., drive or other commands, receive status, position or other information from the drive wheels, etc.). Since the movement or position of the sun (e.g., based on a time of day) is known for various locations, the control system may include information pertaining to the sun movement for a desired location. The control system (e.g., via the one or more control modules) determines the position of the sun (e.g., angular position) at step 200 based on the time of day and the sun movement information. The current position of the collector (e.g., angular position or orientation) is determined at step 202. This may be determined from the motion or status of drive wheels 154 (which may be provided by communication with the drive wheel motor). Since the control system is aware of the amount of rotation (or movement of suspension cable 153 and, hence, collector 114) of the drive wheel for each step (or rotation) of the corresponding motor in each direction of rotation, the status information received from the drive wheels (e.g., motor position, etc.) may be utilized to determine the position or angular orientation of the collector. Various conventional techniques (e.g., coordinate space, trigonometric, distance, slope, etc.) may be utilized to determine the position or angular orientation of the collector.

The position of the sun is compared to the current position of collector 114 to determine a difference between these positions at step 204. The angular position or orientation of the collector is preferably maintained to be aligned with the position of the sun (e.g., to maintain the collector substantially normal to the sun position) for optimal solar energy collection. The difference between the positions of the collector and sun represents the amount of deviation of the collector position from alignment with the sun (e.g., deviation of the collector from being in a position substantially normal to the sun). Various conventional techniques (e.g., coordinate space, trigonometric, distance, etc.) may be utilized to determine the difference in positions between the collector and sun.

Once the difference in position is calculated, the control system (e.g., via the one or more control modules) determines at step 206 the one or more drive wheels to control to adjust the collector position based on the calculated difference for alignment with the sun and optimal collection of solar energy. For example, in the case of stepper or other motors being employed for drive wheels 154, the control system is aware of the amount of rotation (or movement of suspension cable 153 and, hence, collector 114) of the drive wheel for each step (or rotation) of the corresponding motor in each direction of rotation. Thus, the control system determines amount of steps (or rotation of the drive wheel) and direction of the rotation required for each motor of the drive wheels, and provides this information to those drive wheels to adjust the position of the collector to be substantially aligned with the position of the sun. Various conventional techniques (e.g., coordinate space, trigonometric, distance, slope, etc.) may be utilized to determine the adjustments for the position or angular orientation of the collector. This process of adjusting the collector may be performed periodically at desired intervals (e.g., minutes, hours, etc.) to continually adjust the collector position to track the sun.

Alternatively, solar collection system 100 may include one or more sensors 185 (FIG. 1A) (e.g., temperature or thermal sensors to measure coolant fluid or solar cell temperature, current sensors to measure output current of the solar cells, etc.) to determine movement of the sun. In this case, the temperature of the coolant fluid or solar cells, or the amount of current produced by the solar cells, may decrease due to movement of the sun and misalignment of collector 114 with the sun position. Control system 180 may determine controls for drive wheels 154 based on the sensor measurements to adjust the position of collector 114.

Operation of solar collection system 100 is described with reference to FIG. 1A. In particular, collector 114 is oriented for substantial alignment with the position of the sun, and receives solar energy. The collector reflects the solar energy to solar unit 115. Solar cells 109 of solar unit 115 are positioned in facing relation with collector 114 to receive the solar energy reflected from the collector and convert that solar energy to electric power. Coolant layer 110 cools the solar cells with coolant fluid from coolant fluid source 161, and further extracts thermal energy from solar cells 109 (and from solar energy bypassing the solar cells) for conversion to electric power to enhance conversion efficiency of solar energy to electric power. The electric power or output current of solar cells 109 is transported to power system supply grid 120. In addition, the heated coolant fluid from solar unit 115 is transported to electric turbine system 130. The heated coolant fluid may be utilized to generate steam that rotates or otherwise manipulates turbines of electric turbine system 130 to generate electric power. Once the coolant fluid transfers the thermal energy to the electric turbine system, the coolant fluid may return to fluid source 161 for thermal treatment and transfer to solar unit 115. Control system 180 controls drive wheels 154 of support towers 155 to adjust the position of collector 114 to track the sun and maintain optimal solar energy collection. The collection of concentrated solar flux at the ground level for routing photovoltaic output power and thermal output power, via the dual solar collection system, achieves facility outputs approaching megawatts.

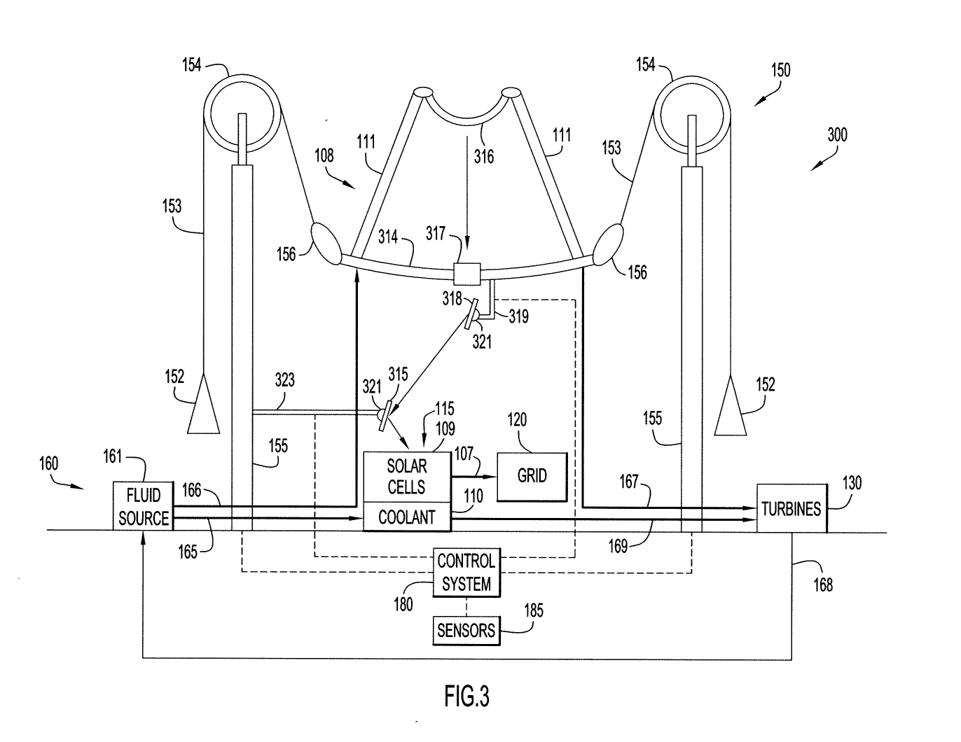

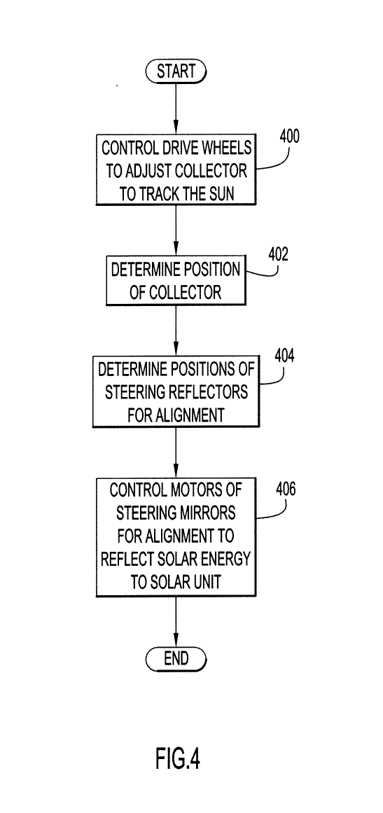

An alternative embodiment for a solar energy collection system is illustrated in FIG. 3. Initially, solar energy collection system 300 is similar to solar energy collection system 100 described above, and includes a Cassegrain type configuration that removes solar unit 115 (e.g., the source of photovoltaic current and coolant flow) from the focal region of the collector (and situates this component on the ground). This is accomplished by employing a secondary reflector 316 and steering reflectors 315, 318 as described below to direct the concentrated solar energy to the conversion devices. The steering reflectors are positioned to enable collection of solar energy regardless of the position of the collector. This embodiment reduces the maintenance complexity by allowing servicing of key components on the ground, and reduces the weight supported by suspension system 150 during tracking mode.

In particular, solar energy collection system 300 includes a collector 314, solar unit 115, secondary reflector 316, steering reflectors 315, 318, suspension system 150, and coolant fluid system 160. Collector 314 includes an integral and generally concave reflective surface that concentrates incoming solar energy (e.g., infrared, visible, etc.) onto secondary reflector 316. The collector includes a substantially central aperture 317 that enables the solar energy reflected by secondary reflector 316 to pass through collector 314 to solar unit 115. The secondary reflector includes an integral and generally convex reflective surface to reflect solar energy from the collector back through the collector aperture. Steering reflector 318 is secured to the underside of collector 314 via a generally ‘L’-shaped post or other securing member 319. The post includes a motorized joint or drive mechanism 321 to enable steering reflector 318 to be positioned in various orientations. The steering reflector is positioned below aperture 317 and oriented to receive solar energy through aperture 317 from secondary reflector 316 and reflect the received energy toward solar unit 115 as described below. Steering reflector 318 is controlled by control system 180 for proper orientation in response to movement of collector 314. The collector and secondary and steering reflectors are preferably implemented by mirrors, but any suitable reflectors may be utilized.

Alternatively, the concave reflective surface of collector 314 may include a segmented surface comprising a plurality of reflective segments 116 as described above for FIG. 1B. The reflective segments may be directly attached to a generally concave substrate 117 (as described above for FIG. 1B), or may be displaced from substrate 117 by a post or other member 119 as described above for FIG. 1C. In this case, substrate 117 may include a reflective surface to enhance efficiency of solar collection. Secondary reflector 316 may similarly include a segmented reflective surface (with reflective segments 116) in substantially the same manner as collector 314 (e.g., as described above for FIGS. 1B-1C).

Solar unit 115 is substantially similar to the solar unit described above, and receives the solar energy collected by collector 314 to enable conversion to electric power. The solar unit includes one or more layers of multi junction solar cells 109 and coolant layer 110 each as described above. Solar cells 109 are positioned above the coolant layer in facing relation with the underside of collector 314 to receive the solar energy reflected from steering reflectors 315, 318 as described below and convert that solar energy to electric power. The solar cells are preferably positioned within each layer to overlap a prior or succeeding layer in order to maximize the capture of solar energy as described above. Coolant layer 110 is disposed below solar cells 109 and cools the solar cells to prevent damage and optimize electrical output. The coolant layer further extracts thermal energy from solar cells 109 for conversion to electric power as described below to enhance conversion efficiency of solar energy to electric power. The coolant layer further receives thermal energy from residual solar energy not being captured by (or bypassing) solar cells 109 within the layers.

Support structure 108 is substantially similar to the support structure described above, and supports secondary reflector 316 at the optimal focus location relative to collector 314 (e.g., the focal point of collector 314). The support structure includes plurality of rods 111 secured to, and extending between, secondary reflector 316 and a peripheral area of collector 314 to support the secondary reflector above the collector. The rods are preferably positioned at substantially equidistant angular positions about collector 314 (e.g., two rods may be displaced from each other by 180°, three rods may be displaced from each other by 120°, etc.), but may be disposed at any suitable positions to support the secondary reflector.

Coolant fluid system 160 is substantially similar to the coolant fluid system described above, and includes coolant fluid source 161 and fluid conduits 165, 166, 167, 168, 169 to transport coolant fluid. Coolant fluid source 161 provides coolant fluid to solar collection system 300, and may include a thermal treatment device to thermally treat coolant fluid, and a pump or other device to direct the coolant fluid through conduits 165, 166. Conduit 166 transports the coolant fluid to steering reflectors 315, 318, and secondary reflector 316. These items should be cooled due to the large heat flux of the solar energy. Conduit 166 may be secured to, or disposed within, a rod 111 of support structure 108 to transport coolant fluid from fluid source 161 to secondary reflector 316. Conduit 166 may further be secured to a tower 155 of suspension system 150 and the underside of collector 314 to transport coolant fluid to steering reflectors 315 and 318. Conduit 166 transports the coolant fluid to steering reflectors 315, 318 and secondary reflector 316 to cool these items and extract thermal energy therefrom.

Conduit 165 is disposed between coolant fluid source 161 and solar unit 115 to transport the coolant fluid to the solar unit. The coolant fluid provided by conduit 165 traverses coolant layer 110 of solar unit 115 to cool solar cells 109 and extract thermal energy therefrom. The coolant fluid further receives thermal energy from residual solar energy not being captured by (or bypassing) solar cells 109 within the layers.

Conduit 167 may be secured to, or disposed within, a rod 111 of support structure 108 to transport heated coolant fluid from secondary reflector 316 to a conventional electric turbine system 130. Conduit 167 may further be secured to a tower 155 of suspension system 150 and the underside of collector 314 to transport coolant fluid from steering reflectors 315 and 318 to the turbine system. Conduit 169 transports the coolant fluid from solar unit 115 to the turbine system. The heated coolant fluid may be utilized to generate steam that rotates or otherwise manipulates turbines of electric turbine system 130 to generate electric power. Once the coolant fluid transfers the thermal energy to the electric turbine system, the coolant fluid may return to fluid source 161 for thermal treatment and transfer to secondary reflector 316, steering reflectors 315, 318, and solar unit 115. Conduit 168 may be disposed between coolant fluid source 161 and electric turbine system 130 to transport the coolant fluid from the electric turbine system to the fluid source in substantially the same manner described above. Conduits 165, 166, 167, 168, 169 may be implemented by any conventional or other conduits suitable for transporting fluids (e.g., tubing, etc.).

An electrical conductor 107 may be secured between solar unit 115 and conventional power system supply grid 120 to transport electrical power from the solar unit (e.g., electric output current from solar cells 109) to the power system supply grid. The electric power from grid 120 and turbine system 130 may be provided for sale to consumers as described above.

Suspension system 150 supports and pivots collector 314 to track movement of the sun for optimal collection of solar energy. Suspension system 150 is substantially similar to the suspension system described above, and includes a plurality of support towers 155 and control system 180. The support towers are preferably positioned at substantially equidistant angular positions about collector 314. For example, three support towers may be disposed about collector 314 and displaced from each other by 120°, while four support towers may be disposed about collector 314 and displaced from each other by 90° as described above for FIG. 1D. However, the towers may be of any quantity and disposed at any suitable positions to support the collector.

Each tower 155 includes counterweight 152, suspension cable 153, and drive wheel 154, each as described above. One end of suspension cable 153 is secured to a peripheral area of collector 314 (e.g., preferably including loop, hook or other engagement member 156 as described above), while the other end of the suspension cable is secured to counterweight 152. The suspension cable extends from collector 314 to enable an intermediate portion (e.g., a portion between collector 314 and counterweight 152) to engage drive wheel 154 as described above. The drive wheel is disposed at an upper portion of tower 155, and is preferably motorized (e.g., driven by a stepper or other motor). Control system 180 controls drive wheels 154 to manipulate suspension cables 153 and pivot collector 314 based on the position of the sun in substantially the same manner described above for FIG. 2. Counterweights 152 greatly reduce the mechanical stress and power necessary to move the collector to track the sun. This is accomplished by allowing the center of gravity of collector 314 to remain stationary while the collector is pivoted to track the movement of the sun as described above.

The collector position is adjusted based on operation of drive wheels 154 of towers 155 as described above. Initially, the collector is suspended below drive wheels 154 of towers 155. Rotation of a drive wheel 154 in a first direction of rotation reels in suspension cable 153 to draw the corresponding peripheral portion of collector 314 upward toward that drive wheel. Conversely, rotation of drive wheels 154 in a second direction of rotation lets out suspension cable 153 to enable the corresponding peripheral portion to move downward. One or more drive wheels may be locked, while other drive wheels may be rotated in order to adjust the orientation of collector 314. For example, in an embodiment employing four towers 155 angularly displaced from each other by 90°, two drive wheels along the azimuth direction may be locked in order to enable the rotation of one or more remaining drive wheels to control elevation. However, any combination of drive wheels may be controlled in any fashion to achieve a desired collector orientation.

The combination of manipulation of drive wheels 154 enable collector 314 to be oriented at various desired angles for substantial alignment with the sun. The quantity of orientation angles to be produced for collector 314 is dependent upon the quantity of towers 155 employed. For example, two towers may enable orientation of collector 314 with respect azimuth or elevation, while three towers may enable orientation of collector 314 with respect to both, but may not quite cover every possible angle. These embodiments typically have a lower collection efficiency since the limited orientation angles for the collector may enable the collector to deviate from alignment with the sun position. Four or more towers substantially cover the spectrum of orientation angles for the collector and provide enhanced collection efficiency; however, the costs of these embodiments are likely to be increased. The solar collection system may employ any quantity of towers based on desired requirements (e.g., costs, collection efficiency, etc.) for a particular application.

Solar energy is reflected by collector 314 to secondary reflector 316, where the solar energy is directed by the secondary reflector back toward the collector and through aperture 317 as described above. Steering reflectors 315, 318 direct the solar energy from aperture 317 to solar cells 109 of solar unit 115 for conversion to electric power. Steering reflector 318 is secured to collector 314 as described above, and reflects solar energy received through aperture 317 toward steering reflector 315. Steering reflector 315 receives solar energy from steering reflector 318 for reflection toward solar unit 115. Steering reflector 315 is secured to a corresponding tower 155 via a post or other securing member 323. The post includes motorized joint or drive mechanism 321 to enable steering reflector 315 to be positioned in various orientations. Steering reflector 315 is positioned below collector 314 and oriented in substantial alignment with steering reflector 318 to reflect solar energy received from steering reflector 318 toward solar unit 115. Steering reflectors 315, 318 are controlled by control system 180 for proper orientation in response to movement of collector 314. Collector 314 may be manipulated to various orientations in order to track movement of the sun as described above. However, certain orientations of collector 314 may significantly impede, or even prevent, alignment between steering reflectors 315, 318, thereby degrading power conversion. Accordingly, solar collection system 300 may include additional steering reflectors 315 secured to one or more other towers 155 in substantially the same manner described above (e.g., secured to a corresponding tower 155 via a post or other securing member 323 with motorized joint or drive mechanism 321). In this case, control system 180 may determine the steering reflector 315 that may provide alignment with steering reflector 318 based on the collector position or orientation, and control these reflectors to be in alignment and provide the solar energy to solar unit 115.

Control system 180 is substantially similar to the control system described above, and preferably includes a conventional or other processor (e.g., microprocessor, computer system, controller, etc.) with one or more control modules to control drive wheels 154 of support towers 155 to position collector 314, and to control drive mechanisms 321 of steering reflectors 315, 318 to position the reflectors to provide solar energy to solar unit 115. The control modules may be implemented by any quantity or combination of hardware and/or software modules or units as described above.

A manner in which control system 180 (e.g., via the one or more control modules) controls the position of collector 314 and steering reflectors 315, 318 is illustrated in FIG. 4. Initially, control system 180 is in communication with each of the drive wheels (and/or motors of the drive wheels) 154 and drive mechanisms 321 to transfer information (e.g., drive or other commands, receive status, position or other information from the drive wheels or mechanisms, etc.). Since the movement or position of the sun (e.g., based on a time of day) is known for various locations, the control system may include information pertaining to the sun movement for a desired location as described above. Specifically, the control system (e.g., via the one or more control modules) determines the position of the sun (e.g., angular position) based on the time of day and the sun movement information, and controls the drive wheels to adjust the collector position for alignment with the sun at step 400 for optimal solar energy collection.

This may be accomplished in substantially the same manner described above for FIG. 2. For example, the current position of the collector (e.g., angular position or orientation) is determined from the motion or status of drive wheels 154 (which may be provided by communication with the drive wheel motor) as described above. The position of the sun is compared to the current position of collector 314 to determine a difference between these positions as described above. The angular position or orientation of the collector is preferably maintained to be aligned with the position of the sun (e.g., to maintain the collector substantially normal to the sun position). The difference between the positions of the collector and sun represents the amount of deviation of the collector position from alignment with the sun (e.g., deviation of the collector from being in a position substantially normal to the sun). Various conventional techniques (e.g., coordinate space, trigonometric, distance, etc.) may be utilized to determine the difference in positions between the collector and sun. Once the difference in position is calculated, the control system (e.g., via the one or more control modules) determines the one or more drive wheels to control to adjust the collector position based on the calculated difference for alignment with the sun and optimal collection of solar energy as described above.

Once the collector position is adjusted in accordance with the sun, the collector position is utilized to adjust positions of steering reflectors 315, 318 to provide solar energy to solar unit 115. In particular, the current position of the collector (e.g., angular position or orientation) is determined at step 402. This may be determined from the prior calculation of collector position described above, or from the motion or status of drive wheels 154 (which may be provided by communication with the drive wheel motor). Since the control system is aware of the amount of rotation (or movement of suspension cable 153 and, hence, collector 114) of the drive wheel for each step (or rotation) of the corresponding motor in each direction of rotation, the status information received from the drive wheels (e.g., motor position, etc.) may be utilized to determine the position or angular orientation of the collector. Various conventional techniques (e.g., coordinate space, trigonometric, distance, slope, etc.) may be utilized to determine the position or angular orientation of the collector.

The positions of steering reflectors 315, 318 for alignment are determined at step 404. Specifically, the position of steering reflector 318 is determined based on the collector position (e.g., since the location of the steering reflector on collector 314 is known). The orientation and coverage of the steering reflectors are known based on the range of drive mechanisms 321. Accordingly, the control system determines the angular orientations of the steering reflectors for alignment with each other, and for reflection of solar energy from steering reflector 315 to solar unit 115. Various conventional techniques (e.g., coordinate space, trigonometric, distance, slope, etc.) may be utilized to determine the position or angular orientation of the steering reflectors.

In the event plural steering reflectors 315 are employed, the control system determines the steering reflector 315 providing alignment with steering reflector 318 for reflection of solar energy to solar unit 115, and determines the corresponding positions or angular orientations of the steering reflectors for the alignment. Various conventional techniques (e.g., coordinate space, trigonometric, distance, etc.) may be utilized to determine the particular steering reflector 315 and positions or angular orientations of the steering reflectors.

Once the positions for the steering reflectors are determined, the control system (e.g., via the one or more control modules) controls drive mechanisms 321 to adjust the positions or angular orientations of steering reflectors 315, 318 for alignment at step 406. For example, in the case of stepper or other motors being employed for drive mechanisms 321, the control system is aware of the amount of movement of the drive mechanism for each step (or movement) of the corresponding motor in each direction of motion. Thus, the control system determines amount of steps (or movement of the drive mechanism) and direction of the movement required for each motor of the drive mechanisms, and provides this information to those drive mechanisms to adjust the position of the steering reflectors to be substantially aligned. Various conventional techniques (e.g., coordinate space, trigonometric, distance, slope, etc.) may be utilized to determine the adjustments for the position or angular orientation of the steering reflectors. This process of adjusting the collector and steering reflectors may be performed periodically at desired intervals (e.g., minutes, hours, etc.) to continually adjust the collector position to track the sun.

Alternatively, solar collection system 300 may include one or more sensors 185 (FIG. 3) (e.g., temperature or thermal sensors to measure temperature of coolant fluid, solar cells, and secondary and steering reflectors, current sensors to measure output current of the solar cells, etc.) to determine movement of the sun, or misalignment of the steering reflectors. In this case, the temperature of the coolant fluid, solar cells or the secondary and steering reflectors, or the amount of current produced by the solar cells, may decrease due to movement of the sun, misalignment of collector 314 with the sun position, and/or misalignment of steering reflectors 315, 318. Control system 180 may determine controls for drive wheels 154 and/or drive mechanisms 321 based on the sensor measurements to adjust the position of collector 314 and/or steering reflectors 315, 318.

Operation of solar collection system 300 is described with reference to FIG. 3. In particular, collector 314 is oriented for substantial alignment with the position of the sun, and receives solar energy. The collector reflects the solar energy to secondary collector 316 that directs the solar energy through aperture 317 of the collector. Steering reflector 315 receives the solar energy reflected through aperture 317, and directs the solar energy to steering reflector 315. Steering reflector 315 further reflects the solar energy to solar unit 115. Solar cells 109 of solar unit 115 are positioned in facing relation with steering reflector 315 to receive the solar energy reflected from steering reflector 315 and convert that solar energy to electric power. Coolant layer 110 cools the solar cells with coolant fluid from coolant fluid source 161, and further extracts thermal energy from solar cells 109 (and from solar energy bypassing the solar cells). Moreover, the coolant fluid may receive thermal energy from the secondary and steering reflectors. The thermal energy captured by the coolant fluid is utilized for conversion to electric power to enhance conversion efficiency of solar energy to electric power. The electric power or output current of solar cells 109 is transported to power system supply grid 120. In addition, the heated coolant fluid from solar unit 115 and/or the secondary and steering reflectors is transported to electric turbine system 130. The heated coolant fluid may be utilized to generate steam that rotates or otherwise manipulates turbines of electric turbine system 130 to generate electric power. Once the coolant fluid transfers the thermal energy to the electric turbine system, the coolant fluid may return to fluid source 161 for thermal treatment and transfer to the solar unit and secondary and steering reflectors. Control system 180 controls drive wheels 154 of support towers 155 and drive mechanisms 321 of steering reflectors 315, 318 to adjust the position of collector 314 and steering reflectors 315, 318 to track the sun and maintain optimal solar energy collection. The collection of concentrated solar flux at the ground level for routing photovoltaic output power and thermal output power, via the dual solar collection system, achieves facility outputs approaching megawatts.

Solar energy collection systems 100, 300 may be modular, where several systems may be combined to enhance power output. For example, two or more solar energy collection systems 100, 300 may be employed in the same or different areas to generate power. These enlarged systems may include any quantity, or any combination of, solar energy collection systems 100, 300.

In order to measure collector performance, the following relationships and parameters may be utilized to determine the lifetime cost of electric power generation (Metric Ratio) and component performance (e.g., based on example parameter values).

Collector Area (A)=pi·radius² (radius <=50 m);

Solar Flux (F)=1 kw per m²;

Solar Cell Area=9-81 m² (heat load dependent);

Solar Cell Efficiency (Ecell)=0.35% (at temperatures of approximately 250° C.);

Thermal Efficiency (Eth)=0.33% (Carnot Efficiency);

Lifetime Hours (30 yr)=88×10³ hours;

Lifetime Power Output=26×10⁶ kw-hrs;

Cost Estimate=$30×10⁶;

Metric Ratio=$0.12−0.013/kw-hr (9−81 m²).

The following relationships contain the basic thermodynamic formulae to determine the thermal cooling flow necessary to maintain the integrity of the multi-junction solar cells. The solar cells are assumed to be germanium or silicon based, which maintain operational capability at temperatures of approximately 250° C. Steam turbines to generate electrical power can work at temperatures below this level, if constrained by solar cell performance at higher temperatures, but with lower Carnot efficiency.

E=M_{PV}·cₚ·dT, and M_{PV}=rho·A·t,

where M_{PV} represents mass, cₚ represents specific heat, A represents area, rho represents density, t represents thickness, and dT represents a temperature rise. With respect to silicon, rho=2.33 gm/cm³, cₚ=700 J/(kg-deg K), and E represents the solar energy input (e.g., in terms of watts).

F=dQ/dT=k·A·dT/X

where F represents the energy flow, k represents watts/(m-deg K), dT represents the temperature gradient, X represents the thickness, and dQ/dT represents the concentration ratio(e.g., 108-970). With respect to Germanium, k=60 watts/(m-deg K).

An example collection system with a collector having a diameter of approximately twenty meters may produce the following power output. Initially, example parameters include the following.

Solar Flux=1 kilowatt (or 10³ watts)/square meter;

Primary Collector Area=pi·(radius)²;

Size of Primary Collector Diameter=20 meters (e.g., size of a house), radius=diameter/2=10 meters;

Conversion Efficiency Solar=35% and Thermal=30%, where the Total Efficiency=65%; and

Solar Cell Area=1−9 square meters.

The Collector/Dish Area=pi·(radius)²=pi·(20 m/2)² square meters=314 square meters.

The Estimated Collected Power (CP) (30 years @ 8 hours/day):
CP=Solar Flux (10³ watts/square meter)·Area (314 square meters)=314·10³ watts;
Days of Operation=365 days·8 hours/day=2,920 hours/year;
Lifetime per 30 years=(2,900*30 years operation)=87,600 hours.

Lifetime Power Output (LPO):
LPO=87,600 hrs·65% (efficiency)·CP (314·10³ watts)=1.8·10¹⁹ kw-hrs.
Divide LPO by 3 to account for rain days to provide a power output estimate of 6.0·10⁹ kw-hrs.

Assuming a cost estimate in the range of $10⁷−$3·10⁷, a Final Performance Metric or Cost for the power is approximately $0.0012/kw-hr to $0.005/kw-hr.

It will be appreciated that the embodiments described above and illustrated in the drawings represent only a few of the many ways of implementing a system and method for collection of solar energy for conversion to electric power.

The collectors may be of any quantity, shape, or size, and include any type of reflective surface (e.g., mirrors or other reflectors, refractors, etc.). The collectors may include any type of surface (e.g., integral, segmented, any sub-portions, etc.) of any suitable geometry (e.g., concave, convex, etc.), and include any types of engagement members (e.g., loop, hooks, etc.) for suspension by the towers. The aperture may be of any quantity, shape or size, and may be disposed within the collector at any location.

The secondary and steering reflectors may be of any quantity, shape, or size, and include any type of reflective surface (e.g., mirrors or other reflectors, refractors, etc.). The reflectors may include any type of surface (e.g., integral, segmented, any sub-portions, etc.) of any suitable geometry (e.g., concave, convex, etc.), and be secured by any types of engagement members (e.g., rods, posts, etc.) of any quantity, shape or size for connection to any suitable components (e.g., collector, tower, ground, etc.). The secondary and steering reflectors may be positioned at any desired location on or relative to the collectors of the solar energy collection systems (e.g., mounted to the collector, locations near the collector, towers, etc.), and provide any desired reflection paths (e.g., linear, folded, etc.) to the solar unit. The steering mirrors may be positioned at any desired locations and orientations relative to each other to provide any desired paths (e.g., linear, folded, etc.) for the solar energy to the solar unit.

The reflective segments may be of any quantity, shape, or size, and include any type of reflective surface (e.g., mirrors or other reflectors, refractors, etc.). The reflective segments may include a surface of any suitable geometry (e.g., concave, convex, etc.), and be secured by any quantity of any types of connection members (e.g., wires, rods, etc.) to any suitable substrate of any shape or size and having any desired reflective properties (e.g., any degree of reflective or absorbent properties, etc.).

The support structure may include any quantity of rods of any shape or size, and disposed at any suitable locations. The support structure may support any desired components for collection of solar energy (e.g., solar unit, secondary or other reflectors, etc.).

The solar unit may include any quantity of solar cells and coolant layers. The solar cells may be of any quantity, and may be implemented by any conventional or other solar cells. The solar cells may be arranged in any fashion (e.g., one or more layers, stacked relation, etc.) to encompass solar energy received by the solar unit. The coolant layer may be implemented by any conventional or other cooling mechanism, may be positioned in any fashion relative to the solar cells, and may utilize any suitable coolant or other thermal fluid. The solar unit may be positioned at any desired location relative to the collectors of the solar energy collection systems (e.g., mounted to the collector, locations near the collector, etc.).

The suspension system may include any quantity of towers positioned at any desired locations relative to the collector of the solar energy collection systems. The towers may be of any shape or size, and include any suitable structures and materials sufficient to suspend the collector. The suspension cables may be of any quantity, shape or size, and may be constructed of any suitable materials with sufficient strength to support the collector. The counterweights may be of any quantity, shape or size, and include any suitable weights to leverage and position the collector.

The drive wheels may be of any quantity, and may be disposed at suitable locations on or relative to the towers. The drive wheels may include any conventional or other types of motors or drive mechanisms (e.g., stepper motor, etc.). The joints or drive mechanisms for the steering reflectors may be of any quantity, and may be disposed at any suitable locations on or relative to any system components (e.g., collector, towers, ground, etc.). The drive mechanisms may include any conventional or other types of motors or drive mechanisms (e.g., stepper motor, etc.).

The fluid system may include any desired thermal fluid to extract thermal energy. The fluid system may include any conventional or other types of thermal treatment (e.g., heating/cooling devices, etc.) and pumping devices (e.g., pumps, valves, suction, etc.) to thermally treat and direct fluid through the conduits. The conduits may be of any quantity, shape or size, and may be disposed at any desired locations to transport the coolant fluid.

The electrical conductor may be of any quantity, shape or size, may be constructed of any suitable conducting materials, and may be disposed at any desired locations to transport electric power. The grid may be implemented by any conventional or other systems to store and/or provide electric power from the solar cells. The turbine systems may be implemented by any conventional or other systems to provide and/or store electric power from the coolant fluid.

The control system may be implemented by any quantity of any personal or other type of computer system or processing device (e.g., IBM-compatible, Apple, Macintosh, laptop, controller, microprocessor, etc.), and may include any commercially available or custom software (e.g., operating system, control modules, etc.). It is to be understood that any software (e.g., control modules, etc.) for the computer systems or processing devices of the present invention embodiments (e.g., control system, etc.) may be implemented in any desired computer language and could be developed by one of ordinary skill in the computer arts based on the functional descriptions contained in the specification and flow charts illustrated in the drawings. Further, any references herein of software performing various functions generally refer to computer systems or processors performing those functions under software control. The computer systems or processing devices of the present invention embodiments may alternatively be implemented by any type of hardware and/or other processing circuitry. The various functions of the computer systems or processing devices may be distributed in any manner among any quantity of software modules or units, processing or computer systems and/or circuitry, where the computer or processing systems may be disposed locally or remotely of each other and communicate via any suitable communications medium (e.g., LAN, WAN, Intranet, Internet, hardwire, modem connection, wireless, etc.). The software and/or algorithms described above and illustrated in the flow charts may be modified in any manner that accomplishes the functions described herein. In addition, the functions in the flow charts or description may be performed in any order that accomplishes a desired operation.

The software of present invention embodiments (e.g., control modules, etc.) may be available on a program product apparatus or device including a recordable or computer usable medium (e.g., magnetic or optical mediums, magneto-optic mediums, floppy diskettes, CD-ROM, DVD, memory devices, etc.) for use on stand-alone systems or systems connected by a network or other communications medium, and/or may be downloaded (e.g., in the form of carrier waves, packets, etc.) to systems via a network or other communications medium.

The control system may employ any conventional or other techniques to determine and adjust the positions of the collector and steering reflectors (e.g., slope, trigonometric, coordinate space, distance, etc.). Further, the collector may be adjusted to be at any desired position or alignment relative to the sun or other solar or other energy source (e.g., normal to the source, any desired angle relative to the source which may dynamically change, etc.).

The collection systems of present invention embodiments may be utilized for any desired energy (e.g., solar, etc.) from any solar or other energy source. Further, the solar units of the collection systems may employ the solar cells and coolant layer either individually or in any combination (e.g., solar cells without the coolant layer, the coolant layer without the solar cells, any quantity or combinations of solar cells and coolant layers, etc.) for generation of electric power by photovoltaic and/or thermal techniques. The quantity and efficiency of electric power generated is based on the particular quantities and types of techniques employed. For example, maximal power generation efficiency is typically achieved by employing photovoltaic techniques in combination with thermal techniques (e.g., solar cells and one or more coolant layers).

The solar cells may be implemented by a conventional or other solar cell array, preferably including one or more layers of semiconductor junctions. The array may be thermally bonded to one or more coolant layers to transfer the solar energy not collected by the solar cell array. The coolant fluid may include any suitable fluids (e.g., solutions, gases, water, anti-freeze type solutions, etc.).

It is to be understood that the terms “top”, “bottom”, “front”, “rear”, “side”, “height”, “length”, “width”, “upper”, “lower”, “vertical” and the like are used herein merely to describe points of reference and do not limit the present invention to any particular orientation or configuration.

From the foregoing description, it will be appreciated that the invention makes available a novel system and method for collection of solar energy for conversion to electric power, wherein a solar energy collection system employs high efficiency, multi junction solar cells in combination with thermal conversion techniques and an efficient suspension system to enhance solar-to-electric power conversion capability.

Having described preferred embodiments of a new and improved system (or apparatus) and method for collection of solar energy for conversion to electric power, it is believed that other modifications, variations and changes will be suggested to those skilled in the art in view of the teachings set forth herein. It is therefore to be understood that all such variations, modifications and changes are believed to fall within the scope of the present invention as defined by the appended claims.

What is claimed is:

1. An apparatus to collect solar energy for conversion to electric power comprising:
a collector including a reflective surface for receiving incoming solar energy;
a suspension system to suspend said collector and adjust a position of said collector in accordance with a position of a source of said solar energy, wherein said suspension system includes a plurality of supports disposed about said collector, and wherein each support is coupled to a peripheral portion of said collector and includes a drive mechanism to manipulate said collector;
a control system to control said drive mechanisms of said suspension system to adjust said position of said collector in accordance with said position of said solar energy source; and
a solar unit for receiving said solar energy from said collector and including a plurality of solar cells to convert said solar energy to electricity.

2. The apparatus of claim 1, further including:
a coolant fluid system to provide coolant fluid; and
wherein said solar unit further includes a coolant layer to enable said coolant fluid to receive thermal energy from at least one of said solar cells and solar energy, and wherein said solar unit provides said electricity and thermal energy for conversion to electric power.

3. The apparatus of claim 1, wherein said plurality of supports are each coupled to said peripheral portions of said collector by a corresponding cable including a counterweight to enable manipulation of said collector.

4. The apparatus of claim 1, wherein said reflective surface of said collector includes a stationary center of gravity during adjustment of collector position.

5. The apparatus of claim 1, further including a support structure to position said solar unit at a focal point of said collector.

6. The apparatus of claim 1, wherein said collector includes an aperture defined therein, and said apparatus further includes:
a secondary reflector to reflect said solar energy from said collector through said aperture; and
a plurality of steering reflectors to direct said solar energy from said aperture along a folded path to said solar unit.

7. The apparatus of claim 6, wherein said plurality of steering reflectors each include a drive mechanism, and said control system adjusts a position of said plurality of steering reflectors in accordance with said position of said collector to align said steering reflectors and direct said solar energy from said aperture to said solar unit.

8. The apparatus of claim 1, further including:
a supply grid to receive and store said electricity produced by said solar cells.

9. The apparatus of claim 2, further including:
a turbine system to receive said thermal energy from said coolant fluid and produce electric power.

10. The apparatus of claim 1, wherein said collector includes a segmented reflective surface including a plurality of reflective segments.

11. A method of collecting solar energy for conversion to electric power comprising:
(a) receiving incoming solar energy via a collector including a reflective surface;
(b) suspending said collector and adjusting a position of said collector in accordance with a position of a source of said solar energy, wherein a plurality of supports are disposed about said collector, and wherein each support is coupled to a peripheral portion of said collector and includes a drive mechanism to manipulate said collector;
(c) controlling said drive mechanisms to adjust said position of said collector in accordance with said position of said solar energy source; and
(d) receiving said solar energy from said collector at a solar unit including a plurality of solar cells to convert said solar energy to electricity.

12. The method of claim 11, further including:
(e) receiving thermal energy from at least one of said solar cells and solar energy via a coolant fluid and providing said electricity and thermal energy for conversion to electric power.

13. The method of claim 11, wherein said plurality of supports are each coupled to said peripheral portions of said collector by a corresponding cable including a counterweight, and step (b) further includes:
(b.1) adjusting said position of said collector by manipulating said cable.

14. The method of claim 11, wherein step (b) further includes:
(b.1) maintaining a center of gravity of said reflective surface of said collector stationary during adjustment of collector position.

15. The method of claim 11, wherein step (d) further includes:
(d.1) receiving said solar energy from said collector at said solar unit positioned at a focal point of said collector.

16. The method of claim 11, wherein said collector includes an aperture defined therein, and step (d) further includes:
(d.1) reflecting said solar energy from said collector through said aperture via a secondary reflector; and
(d.2) directing said solar energy from said aperture along a folded path to said solar unit via a plurality of steering reflectors.

17. The method of claim 16, wherein said plurality of steering reflectors each include a drive mechanism, and step (d) further includes:
(d.3) adjusting a position of said plurality of steering reflectors in accordance with said position of said collector to align said steering reflectors and direct said solar energy from said aperture to said solar unit.

18. The method of claim 11, further including:
(e) receiving and storing said electricity produced by said solar cells at a supply grid.

19. The method of claim 12, further including:
(f) receiving said thermal energy from said coolant fluid and producing electric power at a turbine system.

20. The method of claim 11, wherein said collector includes a segmented reflective surface including a plurality of reflective segments, and step (a) further includes:
(a.1) receiving incoming solar energy via said reflective segments of said segmented reflective surface.
